(19) United States
(12) Patent Application Publication
(10) Pub. No.: US 2022/0416554 A1
(43) Pub. Date: Dec. 29, 2022

(54) CHARGING STAND, ELECTRONIC APPARATUS, AND METHOD FOR OPERATING CHARGING STAND

(71) Applicant: Tatung Technology Inc., Taipei City (TW)

(72) Inventor: Mei-Jung KAN, Taipei City (TW)

(21) Appl. No.: 17/407,238

(22) Filed: Aug. 20, 2021

(30) Foreign Application Priority Data
Jun. 23, 2021 (CN) 202121403513.9

(51) Int. Cl. H02J 7/00; H05K 5/02; H05K 7/14

(52) U.S. Cl. CPC H02J 7/0044; H05K 5/0221; H05K 7/1427

(57) ABSTRACT

The present invention provides a charging stand includes a base, a housing, a circuit board, and a rotatable connector. An upper surface of the housing is formed with an opening. A plurality of sidewalls of the housing are engaged with a periphery of the base, and the housing has an accommodation space inside. The circuit board is disposed on the base. The circuit board is contained in the accommodation space in the housing, and suitable for being connected to an external power supply. The rotatable connector is pivotally connected to the base. The rotatable connector is electrically connected to the circuit board, and is contained in the accommodation space in the housing and visible from the opening.

### CROSS REFERENCE TO RELATED APPLICATION

This application claims the benefits of the Chinese Utility Model Application Serial Number 202121403513.9, filed on Jun. 23, 2021, the subject matter of which is incorporated herein by reference.

### BACKGROUND OF THE INVENTION

### 1. Field of the Invention

The present invention relates to a charging stand and, more particularly, to a charging stand having a plurality of recesses that are favorable to an engagement and having a rotatable connector.

### 2. Description of Related Art

A miniaturized electronic device, such as a portable audio device, is typically equipped with a rechargeable battery cell module. In this way, the devices can be used without connecting to a power supply. In addition, thanks to their small sizes, they can be portable devices.

Generally, while the electronic device is not being used, the users will connect it to a charging stand for charging it. The charging stand is provided with a connector, and the connector can be plugged into the electronic device and used to charge it. However, in the prior arts, when the charging stand is not connected to the electronic device, the connector is exposed to the outside, so the exposed connector looks very unsightly. In addition, when the charging stand is put in a carry-on bag, the exposed connector often punctures other objects and breaks their packages in the bag. Furthermore, the connector itself may be malfunctioned, deformed, or broken, when coming to a collision with a rigid object.

In addition, there are increasing demands to equip set-top boxes, Wi-Fi routers, or audio devices in vehicles. It is needed to fix these devices securely in the vehicles, particularly to let them face toward a certain direction, to obtain a better performance for receiving/transmitting electromagnetic wave or sound. However, the prior arts neither consider using the charging stand to provide the fixing mechanism to the electronic devices, nor even consider a method to charge the electronic devices in the vehicles.

Therefore, it is desirable to provide an improved charging stand to mitigate and/or obviate the aforementioned problems.

### SUMMARY OF THE INVENTION

In this regard, one aspect of the present invention is to provide a charging stand includes a base, a housing, a circuit board, and a rotatable connector. An upper surface of the housing is formed with an opening. A plurality of sidewalls of the housing are engaged with a periphery of the base, and the housing has an accommodation space inside. The circuit board is disposed on the base. The circuit board is contained in the accommodation space in the housing, and suitable for being connected to an external power supply. The rotatable connector is pivotally connected to the base. The rotatable connector is electrically connected to the circuit board, and is contained in the accommodation space in the housing and visible from the opening.

Optionally or preferably, the charging stand is suitable for being connected to an electronic device, and the electronic device is a portable audio, a Wi-Fi router, or a set-top box.

Optionally or preferably, a side of the housing further comprises a heat-dissipation hole adjacent to the opening.

Optionally or preferably, the housing comprises a plurality of recesses, and the electronic device comprises a plurality of protrusions; the recesses and the protrusions are completely engaged with each other in a connected state.

Optionally or preferably, the plurality of the recesses are distributed to locate in corners or a periphery of the housing.

Optionally or preferably, the housing comprises a plurality of protruding components, and the electronic device comprises a plurality of recessing components; the protruding components and the recessing components are completely engaged with each other in a connected state.

Optionally or preferably, in a stored state, the rotatable connector is arranged to be parallel to a plane of the base; in the connected state, the rotatable connector is arranged to be perpendicular to the plane of the base.

Optionally or preferably, in the connected state, the rotatable connector partially extends out of the opening.

Optionally or preferably, the charging stand further comprises a moveable lock piece, set to extend across two sides of the opening; in a locked state, the moveable lock piece retracts into the opening; in an unlocked state, the moveable lock piece extends out of the housing.

Optionally or preferably, the rotatable connector comprises a bouncing structure, configured to switch the rotatable connector from a parallel state to a perpendicular state when being applied by an instantly pressing pressure.

Optionally or preferably, the charging stand further comprises a battery cell module connected to the circuit board, the circuit board being configured such that:

when being connected to the external power supply, the battery cell module and the electronic device are simultaneously charged by the external power supply; and

when not being connected to the external power supply, the electronic device is charged by the battery cell module.

Another aspect of the present invention is to provide an electronic apparatus, formed by combining the charging stand as previously mentioned with an electronic device.

Still another aspect of the present invention is to provide a method for operating a charging stand, performed by using the charging stand as previously mentioned, the method comprising following steps:

Step S1: unlocking a lock of the rotatable connector to allow the rotatable connector to rotate;

Step S2: rotating the rotatable connector; and

Step S3: connecting an electronic device to the charging stand.

Optionally or preferably, the lock in Step S1 is performed by a moveable lock piece or a bouncing structure.

Optionally or preferably, the connection in Step S3 is aligning a plurality of protrusions of the electronic device to a plurality of recesses of the housing.

Other objects, advantages, and novel features of the invention will become more apparent from the following detailed description when taken in conjunction with the accompanying drawings.

### BRIEF DESCRIPTION OF THE DRAWINGS

FIG. 1 is an exploded view of the charging stand, according to an embodiment of the present invention;

FIG. 2 is a schematic diagram illustrating the connection of the charging stand and the electronic device, according to an embodiment of the present invention;

FIG. 3A is a schematic diagram of the locked state of the charging stand, according to an embodiment of the present invention;

FIG. 3B is a schematic diagram of the unlocked state of the charging stand, according to an embodiment of the present invention;

FIG. 3C is a schematic diagram of the locked state of the charging stand, according to another embodiment of the present invention; and

FIG. 4 is a schematic diagram of the electronic apparatus formed by the connection of the charging stand and the electronic device, according to an embodiment of the present invention.

### DETAILED DESCRIPTION OF THE EMBODIMENT

Different embodiments of the present invention are provided in the following description. These embodiments are meant to explain the technical content of the present invention, but not meant to limit the scope of the present invention. A feature described in an embodiment may be applied to other embodiments by suitable modification, substitution, combination, or separation.

It should be noted that, in the present specification, when a component is described to have an element, it means that the component may have one or more of the elements, and it does not mean that the component has only one of the element, except otherwise specified.

Moreover, in the present specification, the ordinal numbers, such as “first” or “second”, are used to distinguish a plurality of elements having the same name, and it does not means that there is essentially a level, a rank, an executing order, or an manufacturing order among the elements, except otherwise specified. A “first” element and a “second” element may exist together in the same component, or alternatively, they may exist in different components, respectively. The existence of an element described by a greater ordinal number does not essentially means the existent of another element described by a smaller ordinal number.

In the present specification, the so-called feature A “or” or “and/or” feature B means A exists solely, B exists solely, or A and B exist at the same time; the so-called feature A “and” feature B means A and B exist at the same time; the so-called “include”, “comprise”, “have”, or “contain” refers to include, but are not limited thereto, except otherwise specified.

Moreover, in the present specification, the terms, such as “top”, “bottom”, “left”, “right”, “front”, “back”, or “middle”, as well as the terms, such as “on”, “above”, “under”, “below”, or “between”, are used to describe the relative positions among a plurality of elements, and the described relative positions may be interpreted to include their translation, rotation, or reflection.

Moreover, in the present specification, when an element is described to be arranged “on” another element, it does not essentially means that the elements contact the other element, except otherwise specified. Such interpretation is applied to other cases similar to the case of “on”.

Moreover, in the present specification, the terms, such as “preferably” or “advantageously”, are used to describe an optional or additional element or feature, and in other words, the element or the feature is not an essential element, and may be ignored in some embodiments.

Moreover, in the present specification, when an element is described to be “suitable for” or “adapted to” another element, the other element is an example or a reference helpful in imagination of properties or applications of the element, and the other element is not to be considered to form a part of a claimed subject matter; similarly, except otherwise specified; similarly, in the present specification, when an element is described to be “suitable for” or “adapted to” a configuration or an action, the description is made to focus on properties or applications of the element, and it does not essentially mean that the configuration has been set or the action has been performed, except otherwise specified.

Moreover, in the present specification, a value may be interpreted to cover a range within ±10% of the value, and in particular, a range within ±5% of the value, except otherwise specified; a range may be interpreted to be composed of a plurality of subranges defined by a smaller endpoint, a smaller quartile, a median, a greater quartile, and a greater endpoint, except otherwise specified.

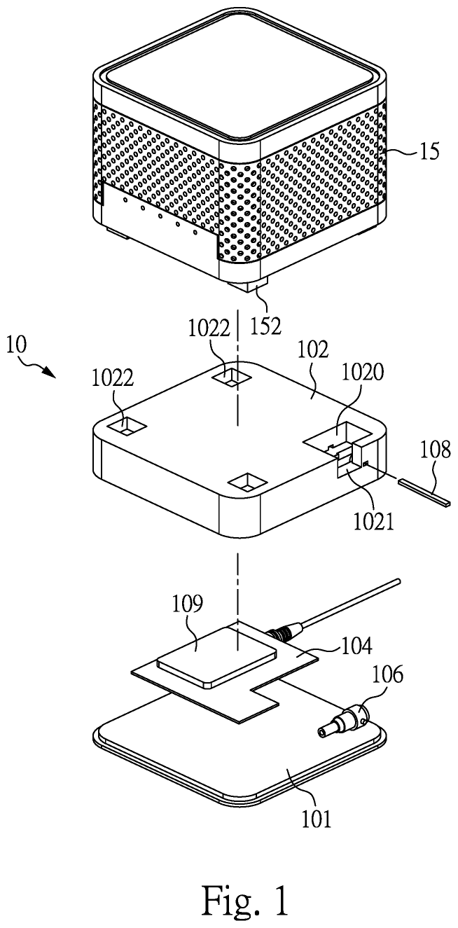

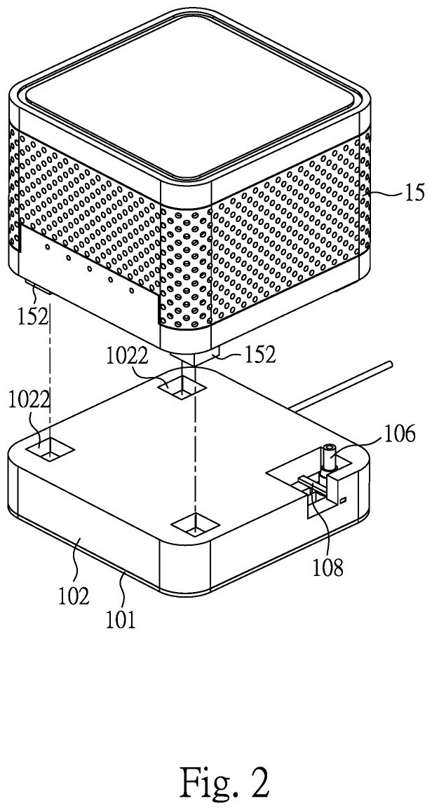

FIG. 1 is an exploded view of the charging stand 10, according to an embodiment of the present invention. FIG. 2 is a schematic diagram illustrating the connection of the charging stand 10 and the electronic device 15, according to an embodiment of the present invention.

As shown in FIG. 1, the charging stand 10 of the present invention includes a base 101, a housing 102, a circuit board 104, and a rotatable connector 106. The housing 102 is formed with an opening 1020, and a plurality of sidewalls of the housing are engaged with a periphery of the base 101. There is provided with an accommodation space in an interior of the housing, which can accommodate a circuit board 104, a rotatable connector 106, and other required elements. In other words, the longitudinal cross section of the housing 102 appears as an inverse-U shape to cover the base 101. The circuit board 104 is provided on the base 101, and can be connected to an external power supply. The power that supplies to the charging stand 10 is typically DC power. In general, a transformer (not illustrated) or a rectifier (not illustrated) may be used to convert AC power into DC power. The rotatable connecter is pivotally connected to the base 101, and it is located corresponding to the position of the opening 1020, so the rotatable connector 106 will become visible from the opening 1020 when observing from the top. In addition, the rotatable connector 106 is electrically connected to the circuit board 104. There is further included a heat dissipation hole 1021 on a side of the housing, adjacent to the opening, used to dissipate the heat generated by charging.

The charging stand 10 is a device suitable for being connected to the electronic device 15 and charging the electronic device 15. In the present specification, a connected state refers to a state that the charging stand 10 is enabled to be connected to an electronic device 15; a stored state refers to a state that the rotatable connector 106 of the charging stand 10 is being rotated below the opening 1020.

With reference to FIG. 2, the charging stand 10 is connected, mainly by the rotatable connector 106, to an electronic device 15, so that it can be charged. In the connected state, the rotatable connector 106 partially extends out of the opening 1020. In FIG. 1 and FIG. 2, a portable audio is cited as an example for the electronic device 15, but the present invention is not limited thereto. The charging stand 10 may also suitably be connected to other devices such as a Wi-Fi router or a set-top box.

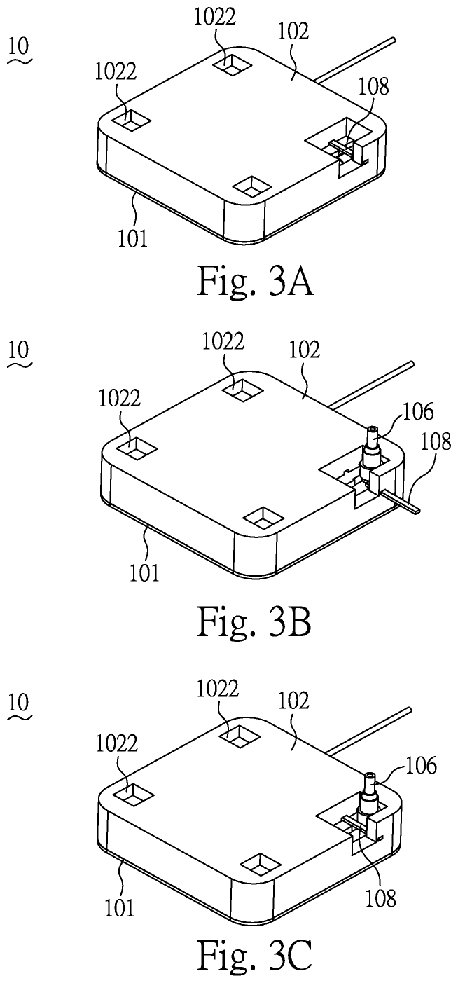

In addition, it should also be noted that the arrangement of the charging stand 10 of the present invention is equipped with the rotatable connector 106 pivotally connected to the base 101, which can be realized by any feasible structure. In the stored state (including the uncharged state), the charging stand 10 is no longer connected to the electronic device 15, and, at this moment, the rotatable connector 106 can be downwardly rotated and stored below the opening 1020 (as shown in FIG. 3A). In comparison with the prior arts, the charging stand 10 is more aesthetically pleasing. Besides, when it needs to be stored in a bag or packet, it will no longer hook other objects by the protruding connector. Moreover, it also saves the storage space.

With reference to FIG. 1 and FIG. 2, in order to make the engagement (including electrical connection and physical connection) between the charging stand 10 and the electronic device 15 stable, the housing 102 may further include a plurality of recesses 1022, and the electronic device 15 may further include a plurality of protrusions 152. The recesses 1022 are distributed adjacent to the corners or the periphery of the housing 102. In the connected state, on one hand, the recesses 1022 and the protrusions 152 are completely engaged with each other, enabling the electrical connection of the rotatable connector 106 and the electronic device 10 to be more stable. On the other hand, it enables the physical engagement between the charging stand 10 and the electronic device 15 to be more stable. As such, when the charging stand 10 is installed in a moving object such as a vehicle, the electronic device will not be separated therefrom just by a slight vibration. Of course, the plurality of the recesses 1022 provided on the housing 102 and the plurality of the protrusions 152 of the electronic device 15 may be accomplished by opposite structures, that is, the housing 102 may be arranged with a plurality of protruding components, and the electronic device 15 may be arranged with a plurality of recessing components, to produce the same effects mentioned above.

Next, please see FIGS. 3A, 3B, and 3C with reference to FIG. 1. FIG. 3A is a schematic diagram of the locked state of the charging stand 10, according to an embodiment of the present invention. FIG. 3B is a schematic diagram of the unlocked state of the charging stand 10, according to an embodiment of the present invention. FIG. 3C is a schematic diagram of the locked state of the charging stand 10, according to another embodiment of the present invention.

The charging stand 10 of the present invention may further include a moveable lock piece 108, set to extend across two sides of the opening 1020. There are a locked state and an unlocked state defined for the moveable lock piece 108. The locked state means the connector 106 is locked by the moveable lock piece 108, and thus, is not allowed to freely rotate; the unlocked state means the connector is not locked, and thus, is allowed to freely rotate. For example, as shown in FIG. 3A, when the moveable lock piece 108 retracts into the opening 1020, the connector 106 is in the locked state; conversely, as shown in FIG. 3B, when the moveable lock piece 108 laterally extends out of the opening 1020, the connector 106 is in the unlocked state.

More specifically, in the locked state, the moveable lock piece 108 is fixed across the two sides of the opening 1020. Both in the situation that the rotatable connector 106 is parallel to the base 101 (such as the stored state shown in FIG. 3A), and in the situation that the rotatable connector 106 is perpendicular to the base 101, the rotatable connector 106 is not allowed to rotate. In the unlocked state, the moveable lock piece 108 extending out of the housing 102, the opening 1020 is no longer locked by the lock piece 108, and, at the moment, the rotatable connector 106 is enabled to freely rotate, so as to be parallel or perpendicular to the base 101.

In addition to using the moveable lock piece 108 to form the locked state or the unlocked state, in another embodiment, the rotatable connector 106 may have a bouncing structure, configured such that: when being applied by an instantly pressing pressure, the rotatable connector can be triggered (for example to bounce up) to switch from a parallel state to a perpendicular state for the latter connection. The bouncing structure may further have a buckle function, configured such that: when being applied by a push, it will slowly lie down from the perpendicular state and restore to be the parallel state.

Please referring back to FIG. 1, the charging stand 10 may further include a battery cell module 109. The battery cell module 109 is connected to the circuit board 104, and the circuit board 104 can be configured such that: when being connected to the external power supply, the power supply module 109 and the electronic device 15 are simultaneously charged by the external power supply; when not being connected to the external power supply, the electronic device 15 is charged by the battery cell module 109. Apparently, the battery cell module 109 can serve as a back-up power supply. If the external power supply fails to work, the battery cell module 109 can serve as the back-up power supply to charge for the electronic device 15.

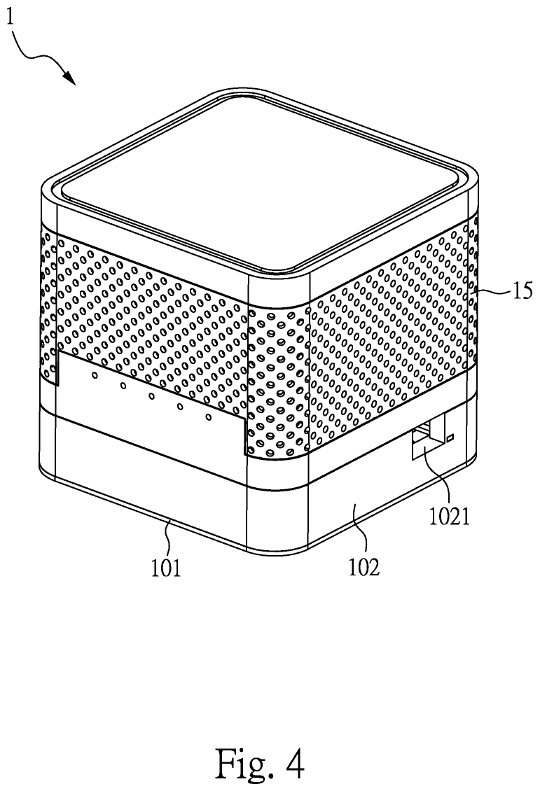

FIG. 4 is a schematic diagram of the electronic apparatus 1 formed by the connection of the charging stand 10 and the electronic device 15, according to an embodiment of the present invention.

As shown in FIG. 4, the charging stand 10 of the present invention may be combined with an electronic device 15 to form an electronic apparatus 1. Under a conceptual framework that the charging stand 10 and the electronic device 15 are integrally designed, the electronic apparatus 1 will have a uniform and aesthetical appearance. FIG. 4 cites a portable audio device for an example. When the charging stand 10 is disposed in a vehicle, the audio device 15 can be charged during driving (playing music and being charged can be at a same time). It is safely and firmly stable. Furthermore, after arriving in the destination, the portable audio has sufficient power so that it can be carried around to play music. So, it is very convenient.

Admittedly, the shapes of the charging stand 10 and the electronic device 15 can be different, but preferably they are the same. In FIG. 4, the charging stand 10 and the electronic device 15 may both be cuboid. In another embodiment, the charging stand 10 and the electronic device 15 may both be cylinder. The area of the cross section of the charging stand 10 can be larger than that of the electronic device 15, so as to maintain its stability.

### Method

According to the description of the aforementioned embodiments, still another embodiment of the present invention provides a method for the operation of the charging stand 10, performed by using the charging stand of one embodiment, and the method includes following steps:

Step S1: unlocking the lock of the rotatable connector 106 to allow the rotatable connector 106 to rotate;

Step S2: rotating the rotatable connector 106; and

Step S3: connecting an electronic device 15 to the charging stand 10.

The lock in the Step S1 can be performed by a moveable lock piece 108 or a bouncing structure.

The connection in the Step S3 is aligning the plurality of the protrusions 152 of the electronic device 15 to the plurality of the recesses 1022 of the housing 102.

To sum up, the charging stand of the present invention has the plurality of the recesses that are favorable to the engagement and has the rotatable connector. In the connected state, those can ensure the engagement of the electronic device to be stable and secure; in the stored state, the rotatable connector can be rotated below the opening and hidden into the housing of the charging stand. It is uniform and neat in appearance so that the required storage space can be saved.

Although the present invention has been explained in relation to its preferred embodiment, it is to be understood that many other possible modifications and variations can be made without departing from the spirit and scope of the invention as hereinafter claimed.

What is claimed is:

1. A charging stand, comprising:
a base;
a housing, wherein an upper surface of the housing is formed with an opening, a plurality of sidewalls of the housing are engaged with a periphery of the base, and the housing has an accommodation space inside;
a circuit board, disposed on the base, contained in the accommodation space in the housing, and suitable for being connected to an external power supply; and
a rotatable connector, pivotally connected to the base, electrically connected to the circuit board, and contained in the accommodation space in the housing and visible from the opening.

2. The charging stand of claim 1, wherein the charging stand is suitable for being connected to an electronic device, and the electronic device is a portable audio, a Wi-Fi router, or a set-top box.

3. The charging stand of claim 2, wherein a side of the housing further comprises a heat-dissipation hole adjacent to the opening.

4. The charging stand of claim 2, wherein the housing comprises a plurality of recesses, and the electronic device comprises a plurality of protrusions; the recesses and the protrusions are completely engaged with each other in a connected state.

5. The charging stand of claim 2, wherein the plurality of the recesses are distributed to locate in corners or a periphery of the housing.

6. The charging stand of claim 2, wherein the housing comprises a plurality of protruding components, and the electronic device comprises a plurality of recessing components; the protruding components and the recessing components are completely engaged with each other in a connected state.

7. The charging stand of claim 1, wherein in a stored state, the rotatable connector is arranged to be parallel to a plane of the base; in the connected state, the rotatable connector is arranged to be perpendicular to the plane of the base.

8. The charging stand of claim 1, wherein in the connected state, the rotatable connector partially extends out of the opening.

9. The charging stand of claim 1, further comprising a moveable lock piece, set to extend across two sides of the opening; in a locked state, the moveable lock piece retracts into the opening; in an unlocked state, the moveable lock piece extends out of the housing.

10. The charging stand of claim 1, wherein the rotatable connector comprises a bouncing structure, configured to switch the rotatable connector from a parallel state to a perpendicular state when being applied by an instantly pressing pressure.

11. The charging stand of claim 3, further comprising a battery cell module connected to the circuit board, the circuit board being configured such that:
when being connected to the external power supply, the battery cell module and the electronic device are simultaneously charged by the external power supply; and
when not being connected to the external power supply, the electronic device is charged by the battery cell module.

12. An electronic apparatus, formed by combining the charging stand of claim 1 with an electronic device.

13. A method for operating a charging stand, performed by using the charging stand,
the charging stand comprising:
a base;
a housing, wherein an upper surface of the housing is formed with an opening, a plurality of sidewalls of the housing are engaged with a periphery of the base, and the housing has an accommodation space inside;
a circuit board, disposed on the base, contained in the accommodation space in the housing, and suitable for being connected to an external power supply; and
a rotatable connector, pivotally connected to the base, electrically connected to the circuit board, and contained in the accommodation space in the housing and visible from the opening;
the method comprising following steps:
Step S1: unlocking a lock of the rotatable connector to allow the rotatable connector to rotate;
Step S2: rotating the rotatable connector; and
Step S3: connecting an electronic device to the charging stand.

14. The method of claim 13, wherein the lock in Step S1 is performed by a moveable lock piece or a bouncing structure.

15. The method of claim 13, wherein the connection in Step S3 is aligning a plurality of protrusions of the electronic device to a plurality of recesses of the housing.
